(19) United States
(12) Patent Application Publication
(10) Pub. No.: US 2025/0151203 A1
(43) Pub. Date: May 8, 2025

(54) METHOD FOR PRODUCING TRANSMISSION SUBSTRATE

(71) Applicants: SUMITOMO ELECTRIC INDUSTRIES, LTD., Osaka (JP); SUMITOMO WIRING SYSTEMS, LTD., Mie (JP); AUTONETWORKS TECHNOLOGIES, LTD., Mie (JP)

(72) Inventors: Yuya TANAKA, Osaka (JP); Yuta MIYAGAWA, Osaka (JP)

(73) Assignees: SUMITOMO ELECTRIC INDUSTRIES, LTD., Osaka (JP); SUMITOMO WIRING SYSTEMS, LTD., Mie (JP); AUTONETWORKS TECHNOLOGIES, LTD., Mie (JP)

(21) Appl. No.: 18/835,728

(22) PCT Filed: Nov. 15, 2022
(86) PCT No.: PCT/JP2022/042376

§ 371 Date: Aug. 4, 2024

(30) Foreign Application Priority Data
Feb. 24, 2022 (JP) 2022-026841

(51) Int. Cl. H05K 3/06

(52) U.S. Cl. CPC H05K 3/064; H05K 2203/0369

(57) ABSTRACT

This transmission board production method is for producing a plurality of transmission boards from a panel having a copper foil on a surface thereof, the plurality of transmission boards each including a transmission path, the transmission board production method including: a resist formation step of forming a photoresist on the copper foil; an exposure step of irradiating the photoresist with light via a photomask; a resist removal step of removing, of the photoresist, either of a part irradiated with the light and a part not irradiated with the light; and an etching step of performing wet etching at a part, of the copper foil, exposed through the resist removal step, using an etching solution. The photomask includes a pattern for forming the transmission path included in each of the plurality of transmission boards, so that the transmission paths are along each other. The photomask is formed so that, of the copper foil, a part around each of a plurality of the transmission paths to be formed through the etching step is removed or remains such that a part where the copper foil remains and a part where the copper foil does not remain are not mixed, through the etching step. In the etching step, the etching solution moves relative to the panel along each transmission path to be formed through the etching step.

### TECHNICAL FIELD

The present disclosure relates to a transmission board production method. This application claims priority on Japanese Patent Application No. 2022-026841 filed on Feb. 24, 2022, the entire contents of which are incorporated herein by reference.

### BACKGROUND ART

In a case of producing a board (hereinafter, referred to as high-speed transmission board) including a wire (hereinafter, referred to as high-speed transmission path) for transmitting a high-frequency signal of 1 GHz or higher by wet etching, a test coupon is used for assuring the impedance of the produced high-speed transmission path. Such test coupons are formed on one panel for producing a plurality of high-speed transmission boards. If the impedances of the test coupons are in accordance with a design value (i.e., within a tolerable range), it is estimated that the impedances of the high-speed transmission paths included in the high-speed transmission boards produced from the same panel are also in accordance with the design value.

For example, PATENT LITERATURE 1 and PATENT LITERATURE 2 shown below each disclose a printed board with a characteristic impedance measurement test coupon provided in an area different from a product wiring area on the printed board. The test coupon in PATENT LITERATURE 1 includes a zig-zag wire portion wired in a zig-zag form so as to have constant wire intervals, and a straight wire portion wired straightly. The test coupon in PATENT LITERATURE 2 has a first wire and a second wire connected in series and according to a first design rule, and a third wire according to a second design rule. The first wire and the second wire have a first straight portion and a second straight portion substantially perpendicular to each other, and the third wire has a third straight portion substantially perpendicular to one of the first straight portion and the second straight portion.

### CITATION LIST

### Patent Literature

PATENT LITERATURE 1: Japanese Laid-Open Patent Publication No. 2011-181785
PATENT LITERATURE 2: Japanese Laid-Open Patent Publication No. 2014-93340

### SUMMARY OF THE INVENTION

A transmission board production method according to one aspect of the present disclosure is for producing a plurality of transmission boards from a panel having a copper foil on a surface thereof, the plurality of transmission boards each including a transmission path, the transmission board production method including: a resist formation step of forming a photoresist on the copper foil; an exposure step of irradiating the photoresist with light via a photomask; a resist removal step of removing, of the photoresist, either of a part irradiated with the light and a part not irradiated with the light; and an etching step of performing wet etching at a part, of the copper foil, exposed through the resist removal step, using an etching solution. The photomask includes a pattern for forming the transmission path included in each of the plurality of transmission boards, so that the transmission paths are along each other. The photomask is formed so that, of the copper foil, a part around each of a plurality of the transmission paths to be formed through the etching step is removed or remains such that a part where the copper foil remains and a part where the copper foil does not remain are not mixed, through the etching step. In the etching step, the etching solution moves relative to the panel along each transmission path to be formed through the etching step.

### BRIEF DESCRIPTION OF DRAWINGS

FIG. 1 is a sectional view showing a structure of a high-speed transmission path having one signal line.

FIG. 2 is a sectional view showing a structure of a high-speed transmission path for transmitting differential signals through two signal lines.

FIG. 3 is a plan view showing an example of a test coupon simulating a high-speed transmission path for transmitting differential signals.

FIG. 4 is a plan view showing a state in which a plurality of test coupons shown in FIG. 3 are formed on one panel.

FIG. 5 is a graph showing an example of a result obtained by measuring the impedance of a produced test coupon.

FIG. 6 is a plan view showing an example of a high-speed transmission board including a high-speed transmission path and produced by a production method according to an embodiment of the present disclosure.

FIG. 7 is a plan view showing arrangement in a case where a plurality of high-speed transmission boards each shown in FIG. 6 are formed on one panel.

FIG. 8 is a sectional view showing a process of the production method according to the embodiment of the present disclosure.

FIG. 9 is a sectional view showing a wet etching process in the production method according to the embodiment of the present disclosure.

FIG. 10 is a plan view showing arrangement in a case where four high-speed transmission boards each shown in FIG. 6 are all formed in the same orientation (i.e., translational symmetry).

FIG. 11 is a plan view showing arrangement in a case where two high-speed transmission boards each shown in FIG. 6 are formed on one panel.

FIG. 12 is a plan view showing arrangement of a plurality of high-speed transmission boards on one panel in a production method according to a first modification.

FIG. 13 is a plan view showing arrangement of a plurality of high-speed transmission boards on one panel in a production method according to a second modification.

FIG. 14 is a plan view showing arrangement in a case where two high-speed transmission boards each shown in FIG. 6 and a disposal portion are formed on one panel.

FIG. 15 is a plan view showing arrangement of a plurality of high-speed transmission boards on one panel in a production method according to a third modification.

FIG. 16 is a plan view showing an example of a high-speed transmission board including a high-speed transmission path and produced by a production method according to a fourth modification.

FIG. 17 is a plan view showing arrangement in a case where a plurality of high-speed transmission boards each shown in FIG. 16 are formed on one panel.

FIG. 18 is a plan view showing arrangement in a case where four high-speed transmission boards each shown in FIG. 16 are all formed in the same orientation (i.e., translational symmetry).

FIG. 19 is a plan view showing arrangement in a case where two high-speed transmission boards each shown in FIG. 16 are formed on one panel.

FIG. 20 is an enlarged plan view showing a pattern corresponding to a high-speed transmission path and an area therearound on a photomask.

### DETAILED DESCRIPTION

### Problems to be Solved by the Present Disclosure

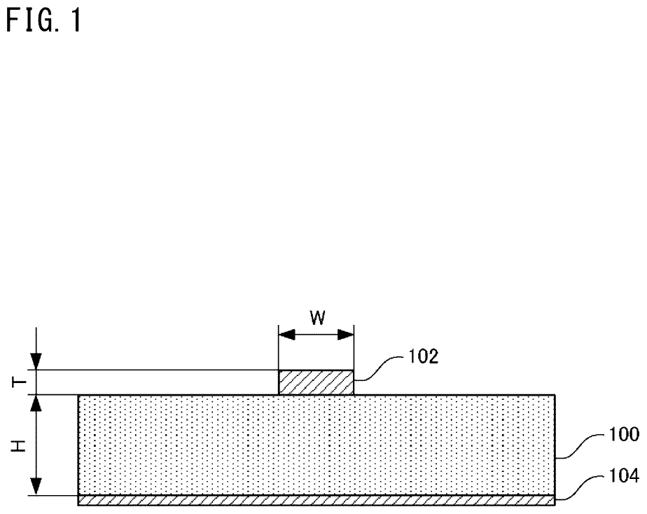

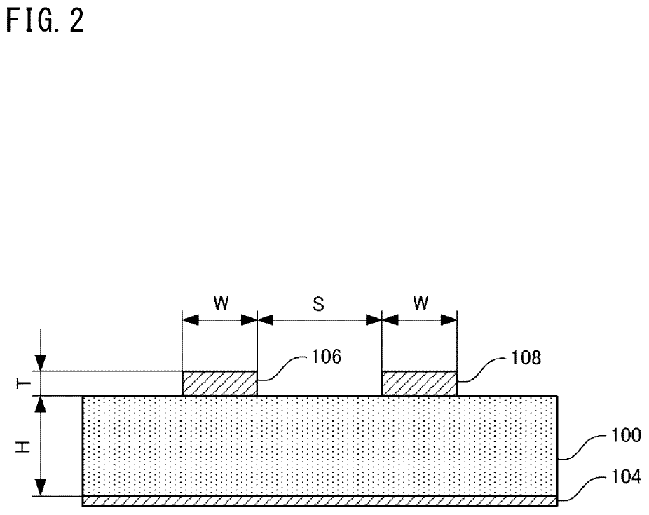

In terms of production efficiency, a plurality of transmission boards (i.e., boards including wires for transmitting signals) are produced from one panel (e.g., one side is several tens of cm), but it is known that wires on the transmission boards are not formed in accordance with design dimensions and there are variations in their impedances. In particular, regarding high-speed transmission paths, the influence of dimensional accuracy on variations in impedances is great. For example, with reference to FIG. 1, the impedance of a high-speed transmission path having one signal line is represented as a function of a width W and a thickness T of a conductive member 102 which is a wire for transmitting a signal, and a height H and a permittivity of a dielectric member 100 placed between a conductive member 104 and the conductive member 102. As another example, with reference to FIG. 2, the impedance of a high-speed transmission path for transmitting differential signals through two signal lines is represented as a function of a width W and a thickness T of each of a conductive member 106 and a conductive member 108 which are the two signal lines, a distance S therebetween, and a height H and a permittivity of the dielectric member 100. Therefore, the impedance is influenced by dimensional accuracy.

As a problem, it is known that the impedance of a transmission path (i.e., a wire for transmitting a signal) included in a transmission board varies in accordance with the position of each of a plurality of transmission boards formed on one panel. As a cause for the variations, non-uniformity of wet etching on one panel is conceivable. This problem cannot be solved by the methods of forming test coupons as disclosed in PATENT LITERATURE 1 and PATENT LITERATURE 2.

Accordingly, an object of the present disclosure is to provide a transmission board production method that can suppress variations from a design value with respect to the impedances of transmission paths included in transmission boards.

### Effects of the Present Disclosure

According to the present disclosure, it is possible to provide a transmission board production method that can suppress variations from a design value with respect to the impedances of transmission paths included in transmission boards.

### Description of Embodiment of the Present Disclosure

Features of an embodiment of the present disclosure are listed and described. At least parts of the embodiment described below may be arbitrarily combined.

(1) A transmission board production method according to one aspect of the present disclosure is for producing a plurality of transmission boards from a panel having a copper foil on a surface thereof, the plurality of transmission boards each including a transmission path, the transmission board production method including: a resist formation step of forming a photoresist on the copper foil; an exposure step of irradiating the photoresist with light via a photomask; a resist removal step of removing, of the photoresist, either of a part irradiated with the light and a part not irradiated with the light; and an etching step of performing wet etching at a part, of the copper foil, exposed through the resist removal step, using an etching solution. The photomask includes a pattern for forming the transmission path included in each of the plurality of transmission boards, so that the transmission paths are along each other. The photomask is formed so that, of the copper foil, a part around each of a plurality of the transmission paths to be formed through the etching step is removed or remains such that a part where the copper foil remains and a part where the copper foil does not remain are not mixed, through the etching step. In the etching step, the etching solution moves relative to the panel along each transmission path to be formed through the etching step. Thus, variations from a design value with respect to the impedances of transmission paths included in a plurality of transmission boards produced from one panel, can be suppressed.

(2) In the above (1), the transmission path may include a first connection portion to which a semiconductor element is connected, and a second connection portion to which a connector is connected. The transmission path, the first connection portion, and the second connection portion may be arranged so as to be decentered in a predetermined orientation from a center of the transmission board. At least two said transmission boards may be produced from the panel. The photomask may be formed so that, of the copper foil, a part around each of a plurality of the transmission paths to be formed through the etching step remains such that a part where the copper foil remains and a part where the copper foil does not remain are not mixed, through the etching step. In the photomask, at least a pair of the patterns may be arranged at 2-fold rotational symmetry positions closely to each other. Thus, in wet etching of the panel, the etching speeds at parts where respective transmission paths are formed can be made uniform, and variations in the impedances of the transmission paths can be suppressed.

(3) In the above (1), the transmission path may include a first connection portion to which a semiconductor element is connected, and a second connection portion to which a connector is connected. The transmission path, the first connection portion, and the second connection portion may be arranged in a first area adjacent to an outer periphery of the transmission board, so as to be decentered in a predetermined orientation from a center of the transmission board. The photomask may be formed so that, of the copper foil, a part around each of a plurality of the transmission paths to be formed through the etching step remains such that a part where the copper foil remains and a part where the copper foil does not remain are not mixed, through the etching step. The panel may include a disposal portion which is a part in a range of a predetermined distance from an outer periphery of the panel and which does not form the transmission board. The disposal portion may be located adjacently to the first area of at least one of the transmission boards. The copper foil may remain on the disposal portion, after the etching step. Thus, in wet etching of the panel, the etching speeds at parts where respective transmission paths are formed can be made uniform, and variations in the impedances of the transmission paths can be suppressed.

(4) In the above (3), the predetermined distance may be not less than 2 cm. Thus, variations in the impedances of the transmission paths can be more suppressed.

(5) In the above (1), the transmission path may include a first connection portion to which a semiconductor element is connected, and a second connection portion to which a connector is connected. The transmission path, the first connection portion, and the second connection portion may be arranged in a first area so as to be decentered in a predetermined orientation from a center of the transmission board. The transmission board may include a second area where the copper foil remains after the etching step. The second area may be located on a side opposite to the first area across a center of the transmission board. At least two said transmission boards may be produced from the panel. The photomask may be formed so that, of the copper foil, a part around each of a plurality of the transmission paths to be formed through the etching step is removed such that a part where the copper foil remains and a part where the copper foil does not remain are not mixed, through the etching step. In the photomask, at least a pair of the patterns may be arranged at 2-fold rotational symmetry positions away from each other. Thus, in wet etching of the panel, the etching speeds at parts where respective transmission paths are formed can be made uniform, and variations in the impedances of the transmission paths can be suppressed.

(6) In the above (1), the transmission path may be an antenna. Thus, variations in the impedances of antennas included in a plurality of transmission boards produced from one panel can be suppressed.

(7) In any one of the above (1) to (6), the photomask may include, for each of a plurality of the patterns, a predetermined area for forming, of the copper foil, a part to be removed or remain such that a part where the copper foil remains and a part where the copper foil does not remain are not mixed, through the etching step. Of outer edges of the predetermined area, a predetermined outer edge along the pattern may be away from the pattern by 4 cm or more. Thus, in wet etching of the panel, the etching speeds at parts where respective transmission paths are formed can be made more uniform, and variations in the impedances of the transmission paths can be more suppressed.

(8) In the above (7), for each of a plurality of the patterns, the predetermined outer edge may be away from the pattern by 6 cm or more. Thus, in wet etching of the panel, the etching speeds at parts where respective transmission paths are formed can be made even more uniform, and variations in the impedances of the transmission paths can be even more suppressed.

(9) In the above (8), for each of a plurality of the patterns, the predetermined outer edge may be away from the pattern by 12 cm or more. Thus, in wet etching of the panel, the etching speeds at parts where respective transmission paths are formed can be made still even more uniform, and variations in the impedances of the transmission paths can be still even more suppressed.

### Details of Embodiment of the Present Disclosure

In the following embodiment, the same parts are denoted by the same reference signs. They are also the same in name and function. Therefore, the detailed description thereof will not be repeated. In the following description, the word “direction” means both of one orientation and an orientation opposite thereto.

### Experiment and Consideration

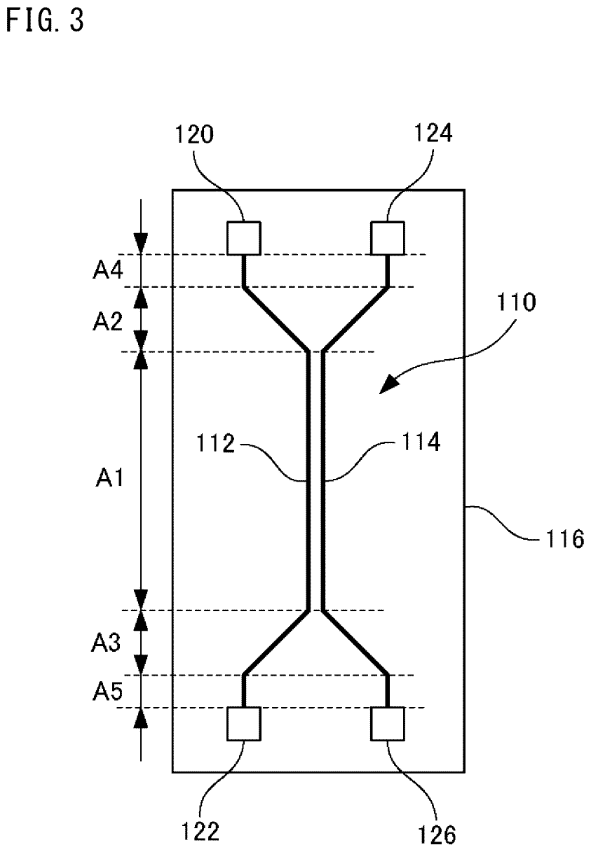

The width of a 100Ω path of a normal multilayer board is designed to be around 100 μm, but in an actually produced board, there are variations of about ±10Ω at maximum. Regarding production of a plurality of high-speed transmission boards from one panel by wet etching, a preliminary experiment was conducted for desirable arrangement of a plurality of high-speed transmission boards on a panel. With reference to FIG. 3, a test coupon 110 simulating a high-speed transmission path was used. The test coupon 110 includes a conductive wires 112 and 114 of copper or the like formed on a board 116 of resin or the like, conductive terminal portions 120 and 122 provided at both ends of the wire 112, and conductive terminal portions 124 and 126 provided at both ends of the wire 114. The board 116 has a rectangular shape with a length of about 8 cm and a width of about 4 cm.

The wire 112 and the wire 114 are bent and formed of straight wire parts in areas A1 to A5. In the area A1, the wire 112 and the wire 114 are close to each other and arranged in parallel with a predetermined interval therebetween. In each of the area A2 and the area A3, the wire 112 and the wire 114 are arranged with an angle of 90 degrees therebetween. In each of the area A4 and the area A5, the wire 112 and the wire 114 are away from each other and arranged in parallel. The wire 112 and the wire 114 simulate a high-speed transmission path for transmitting differential signals. The design value of the impedance of the test coupon 110 was 100Ω.

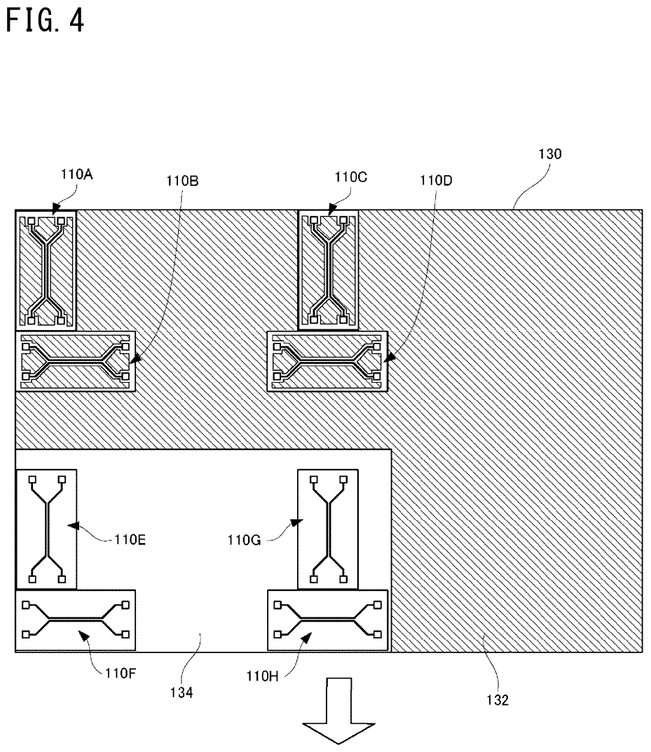

With reference to FIG. 4, by wet etching, eight test coupons 110 each shown in FIG. 3 are formed on a panel 130. The panel 130 has a rectangular shape with a length of about 34 cm and a width of about 48 cm, for example. The panel 130 before etching is a flat plate formed of resin or the like, and a copper foil is formed over the entirety of one of both surfaces thereof. On the copper foil of the panel 130, a photoresist was formed by application or the like, and one photomask was placed thereon. Then, light (e.g., UV (ultraviolet) light) for altering (e.g., curing) the photoresist was applied. By arrangement shown in FIG. 4, test coupons 110A to 110H having the same specifications (i.e., specified shape and size) as the test coupon 110 shown in FIG. 3 were formed. That is, the photomask was formed so that the test coupons 110A to 110D were formed in a copper foil area 132 (see hatched area) and the test coupons 110E to 110H were formed in a resin area 134 where there was no copper foil and resin was exposed. After the resist was irradiated with light via the photomask, a part altered through irradiation of light or a part not irradiated with light, was removed. In a case of using a negative photoresist, the resist is cured (e.g., photopolymerized) when irradiated with light, and therefore a part not irradiated with light is removed by an organic solvent or the like. In a case of using a positive photoresist, a part irradiated with light is altered and is removed by an alkali solution or the like.

Thereafter, the panel 130 on which the photoresist remains was subjected to wet etching using an etching solution. Then, the test coupons 110A to 110H were cut away from the panel 130, and the impedances of the test coupons were measured. In the wet etching, as described later, in a tank filled with the etching solution, the panel 130 was moved at a constant speed in an orientation indicated by a downward arrow in FIG. 4. Therefore, relationships between the orientation (hereinafter, referred to as flow orientation) in which the panel is moved in the etching solution and the directions along the wires in the areas A1 (see FIG. 1) of the test coupons 110A to 110H are different from each other. That is, the test coupon 110A, the test coupon 110C, the test coupon 110E, and the test coupon 110G are along the flow orientation. The test coupon 110B, the test coupon 110D, the test coupon 110F, and the test coupon 110H are approximately perpendicular to the flow orientation. For measurement of the impedances, TDR (Time Domain Reflectometory) was used.

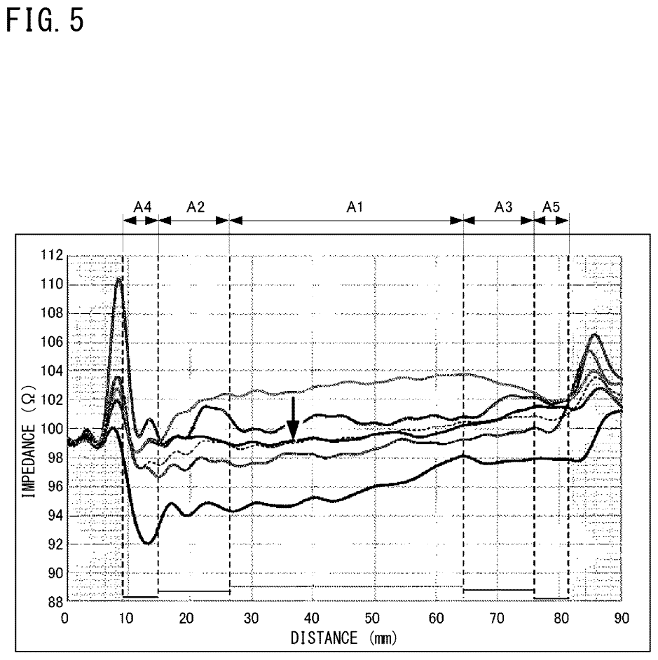

Five panels were used in total, and on each panel, the same photomask was used to form the test coupons 110A to 110H as shown in FIG. 4, and then the test coupons 110A to 110H were cut away from each panel, thus producing five of each test coupon 110A to 110H. The test coupons are for transmission of differential signals, and the design value of the impedances thereof is 100Ω as described above. As an example, FIG. 5 shows a result obtained by measuring the impedances for the five test coupons 110A. The vertical axis indicates the impedance (unit: Ω). The horizontal axis indicates a distance (unit: mm) representing a measurement position, i.e., a length along the wire 112 and the wire 114 shown in FIG. 3. In FIG. 5, the areas A1 to A5 shown in FIG. 3 are shown correspondingly to wire lengths. Six graphs shown in FIG. 5 represent measurement data of the five test coupons 110A, and the average value thereof (i.e., a solid-line graph indicated by a downward arrow in FIG. 5). Thus, even among the test coupons formed at the same location on the panels, the impedances vary. Also for the test coupons 110B to 110H, graphs that exhibit variations were similarly obtained.

The measurement data obtained for five of each test coupon 110A to 110H were evaluated, and a condition for obtaining impedances in which variations are small and which are close to the design value (i.e., 100Ω, was considered. Specifically, considering the electromagnetic coupling state between the wire 112 and the wire 114, the wire 112 and the wire 114 were classified into two kinds of areas, to perform evaluation. That is, the impedance of a part in the area A1 shown in FIG. 3 was considered to be an impedance with coupling, and the impedance of parts in the areas A2 to A5 was considered to be an impedance without coupling. The average values (Z1 and Z2, respectively) of these impedances, variations (σ1 and σ2, respectively) in the impedances, and a difference (i.e., |Z1−Z2|) between the impedance with coupling and the impedance without coupling, were calculated, and then were scored. Here, Z1 is the average value of the impedance with coupling, i.e., in the area A1, and Z2 is the average value of the impedance without coupling, i.e., in the areas A2 to A5. In the areas A2 to A5, the two wires 112 and 114 are perpendicular to each other or away from each other, and therefore are considered to be not subjected to electromagnetic coupling. The variations (i.e., σ1 and σ2) in the impedances are differences between the maximum value and the minimum value. Here, σ1 is a variation in the impedance with coupling, i.e., in the area A1, and σ2 is a variation in the impedance without coupling, i.e., in the areas A2 to A5.

From measurement data for five of each test coupon 110A to 110H, the above values Z1 and Z2 were calculated, and for each value, scoring was performed in accordance with a difference from the design value 100Ω, to obtain an evaluation score. That is, if the difference between Z1 and 100Ω was not less than 0Ω and not greater than 2Ω, the score was 3 points; if the difference was greater than 2Ω and not greater than 3Ω, the score was 2 points; if the difference was greater than 3Ω and not greater than 4Ω, the score was 1 point; and if the difference was greater than 4Ω, the score was 0 points. Similarly, regarding Z2, if the difference between Z2 and 100Ω was not less than 0 and not greater than 2Ω, the score was 3 points; if the difference was greater than 2Ω and not greater than 3Ω, the score was 2 points; if the difference was greater than 3Ω and not greater than 4Ω, the score was 1 point; and if the difference was greater than 4Ω, the score was 0 points. In addition, σ1 and σ2 were calculated and scoring was performed in accordance with the values thereof. That is, if σ1 was not less than 0Ω and not greater than 2Ω, the score was 4 points; if σ1 was greater than 2Ω and not greater than 3Ω, the score was 3 points; if σ1 was greater than 3Ω and not greater than 4Ω, the score was 2 points; if σ1 was greater than 4Ω and not greater than 5Ω, the score was 1 point; and if σ1 was greater than 5Ω, the score was 0 points. Similarly, regarding 62, scoring was performed. In addition, if |Z1−Z2| was not less than 0Ω and not greater than 2Ω, the score was 4 points; if |Z1−Z2| was greater than 2Ω and not greater than 4Ω, the score was 3 points; if |Z1−Z2| was greater than 4Ω and not greater than 6Ω, the score was 2 points; if |Z1-Z2| was greater than 6Ω and not greater than 8Ω, the score was 1 point; and if |Z1−Z2| was greater than 8Ω, the score was 0 points.

Further, using the evaluation scores obtained as described above, α1 and α2 were calculated by the following formulae, and then the sum of these, α3(=α1+α2), was calculated.

$$α 1 = {P}_{Z 1} \times {P}_{σ 1} \times 50 / {[ {P}_{Z 1} \times {P}_{σ 1} ]}_{Max}$$

$$α2 = {P}_{Z 2} \times {P}_{σ 2} \times {P}_{\vert Z 1 - Z 2 \vert} \times 50 / {[ {P}_{Z 2} \times {P}_{σ2} \times {P}_{\vert Z 1 - Z 2 \vert} ]}_{Max}$$

In the above formulae, P_{Z1}, P_{Z2}, P_{σ1}, P_{σ2}, and P_{|Z1-Z2|} are the evaluation scores determined as described above from Z1, Z2, σ1, σ2, and |Z1−Z2| calculated from the measurement data. In addition, [P_{Z1}χP_{σ1}]_{Max} is the maximum value of a product of the evaluation score P_{Z1} and the evaluation score P_{σ1}, and [P_{Z2}×P_{σ2}×P_{|Z1-Z2|}]_{Max} is the maximum value of a product of the evaluation score P_{Z2}, the evaluation score P_{σ2}, and the evaluation score P_{|Z1-Z2|}.

The value range of α3 is 0 to 100. It is more preferable that α3 is greater, and it can be said that, when α3 is closer to “100”, the impedance is closer to the design value and the variation is smaller (hereinafter, described as “production result is good”). The values of α3 for the test coupons 110A to 110H were 18.8, 32.8, 78.1, 39.8, 75.0, 49.2, 78.1, and 15.6, respectively. From this result, the following have been found regarding preferable arrangement of test coupons.
If test coupons are arranged along the flow orientation of wet etching, the production result is good.
The production result of a test coupon at a center of the panel is good.
Uniformity of a copper foil around test coupons (i.e., the degree to which a part where a copper foil is present and a part where a copper foil is absent are not mixed) greatly influences the production result.
In a case where a copper foil around test coupons is not uniform, i.e., in a case where a part where a copper foil is present and a part where a copper foil is absent are mixed, it is preferable that a test coupon arranged along the flow orientation of wet etching is placed at a center of the panel.
In a case where a copper foil around test coupons is not uniform, it is preferable that the test coupon not arranged along the flow orientation of wet etching is placed at an end of the panel.

Accordingly, regarding the impedances of high-speed transmission paths, in order to suppress variations from the design value, it is preferable that the high-speed transmission paths are arranged along the flow orientation of wet etching. In addition, it is preferable that, in a predetermined area around a high-speed transmission path, a copper foil is uniformly present or a copper foil is uniformly absent (i.e., absence is uniform).

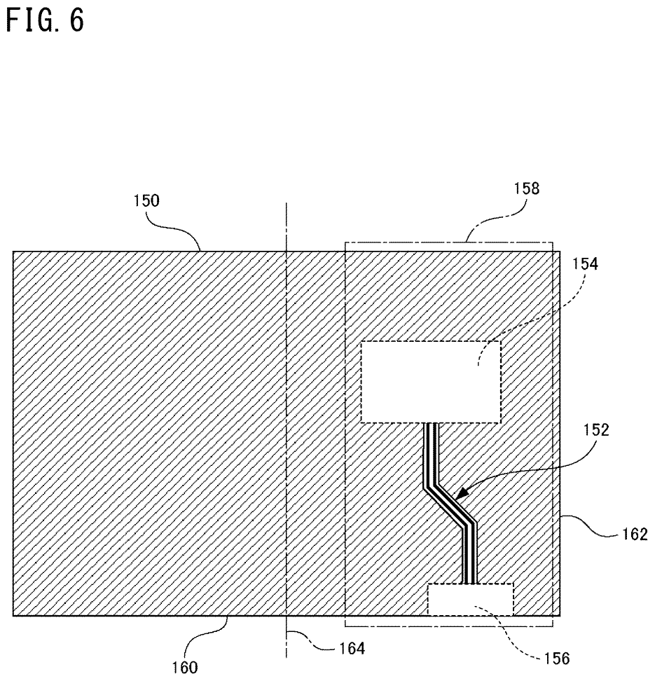

Considering the result of the preliminary experiment described above, a high-speed transmission board production method according to the embodiment of the present disclosure will be described below. With reference to FIG. 6, a high-speed transmission board 150 which is an example of a production target includes a high-speed transmission path 152, a chip mounting area 154 for mounting a semiconductor element (e.g., a semiconductor IC (Integrated Circuit) such as a high-speed interface chip), and a connector mounting area 156 for mounting a high-frequency connector or the like. The high-speed transmission board 150 is formed by performing wet etching at a copper foil formed on a flat plate of resin or the like. A part where the copper foil is present is shown by hatching. The high-speed transmission path 152 is a wire for connecting the semiconductor element and the connector placed together on the high-speed transmission board 150 and transmitting a high-frequency signal of 1 GHz or higher. The high-speed transmission path 152 includes a first terminal portion and a second terminal portion (which are not shown) to which the semiconductor element and the connector are respectively connected, as with the terminal portion 120 and the like shown in FIG. 3. In FIG. 6, the chip mounting area 154 is located away from the outer periphery (i.e., four sides) of the high-speed transmission board 150, and the connector mounting area 156 is located adjoining a part (specifically, a lower side 160) of the outer periphery of the high-speed transmission board 150. Arrangement of the chip mounting area 154 and the connector mounting area 156 is not limited to that shown in FIG. 6. The high-speed transmission path 152 is formed of two wires and transmits differential signals. In the drawing, the chip mounting area 154 and the connector mounting area 156 are not hatched and wire patterns are not shown there, but wire patterns corresponding to terminals of the semiconductor element and the connector mounted in the respective areas are formed. The wire patterns formed in the chip mounting area 154 and the connector mounting area 156 also include wire patterns connected to the high-speed transmission path 152.

The high-speed transmission path 152, the chip mounting area 154, and the connector mounting area 156 are arranged so as to be decentered in a predetermined orientation from the center of the high-speed transmission board 150. That is, the high-speed transmission path 152, the chip mounting area 154, and the connector mounting area 156 are arranged in a first area 158 located at the right of a center line 164 of the high-speed transmission board 150 perpendicular to the lower side 160 of the high-speed transmission board 150. Thus, the semiconductor element and the connector respectively mounted in the chip mounting area 154 and the connector mounting area 156 are also arranged at positions decentered in a predetermined orientation from the center of the high-speed transmission board 150. The direction of the high-speed transmission path 152 (i.e., upward and downward orientations in FIG. 6) is along a right side 162. Each wire of the high-speed transmission path 152 is formed of three kinds of straight portions. The central straight portion extends obliquely, and the straight portions on both sides thereof extend along the right side 162. The direction of the high-speed transmission path 152 means, regarding the straight portions forming the high-speed transmission path 152, a direction along the straight portions where the sum of the lengths of parallel straight portions is greatest. Also in a case where the shape of a high-speed transmission path formed on the high-speed transmission board 150 is different from the shape of the high-speed transmission path 152 shown in FIG. 6, the direction of the high-speed transmission path is defined in the same manner. That is, regarding a plurality of straight portions forming the high-speed transmission path, a direction along the straight portions where the sum of the lengths of parallel straight portions is greatest is defined as the direction of the high-speed transmission path.

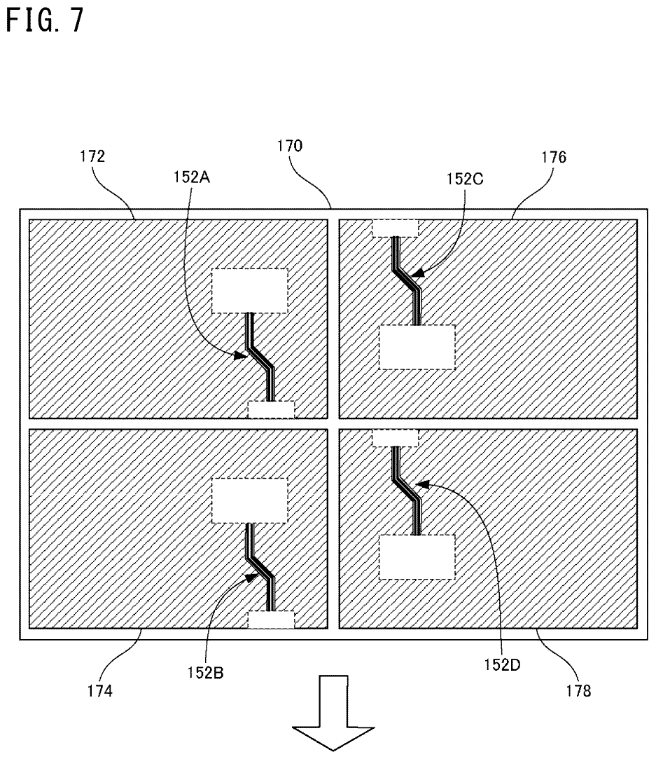

Using one panel, a plurality of the high-speed transmission boards 150 can be produced. With reference to FIG. 7, using one panel 170, in wet etching, the panel 170 is moved in an etching solution in an orientation indicated by a downward arrow, whereby four high-speed transmission boards 150 (i.e., high-speed transmission boards 172 to 178) are produced. In FIG. 7, hatched areas represent parts where copper foils remain after the wet etching. The high-speed transmission board 172 and the high-speed transmission board 174 are formed in the same orientation (i.e., translational symmetry) as the high-speed transmission board 150, and the high-speed transmission board 176 and the high-speed transmission board 178 are formed in a state in which the high-speed transmission board 150 is rotated by 180 degrees. That is, regarding the high-speed transmission board 172 and the high-speed transmission board 176 arranged adjacently in a direction perpendicular to the flow orientation of the wet etching, a high-speed transmission path 152A and a high-speed transmission path 152C are arranged in a 2-fold rotational symmetry form closely to each other (i.e., in a center area of the panel 170). Similarly, a high-speed transmission path 152B formed on the high-speed transmission board 174 and a high-speed transmission path 152D formed on the high-speed transmission board 178 are arranged in a 2-fold rotational symmetry form closely to each other. By using a photomask for forming the high-speed transmission boards 172 to 178 as described above, in wet etching, a state in which a copper foil is uniformly present around each of the high-speed transmission paths 152A to 152D can be realized. That is, such a photomask that a copper foil uniformly remains around each of the formed high-speed transmission paths 152A to 152D after etching, is used.

### [Production Method]

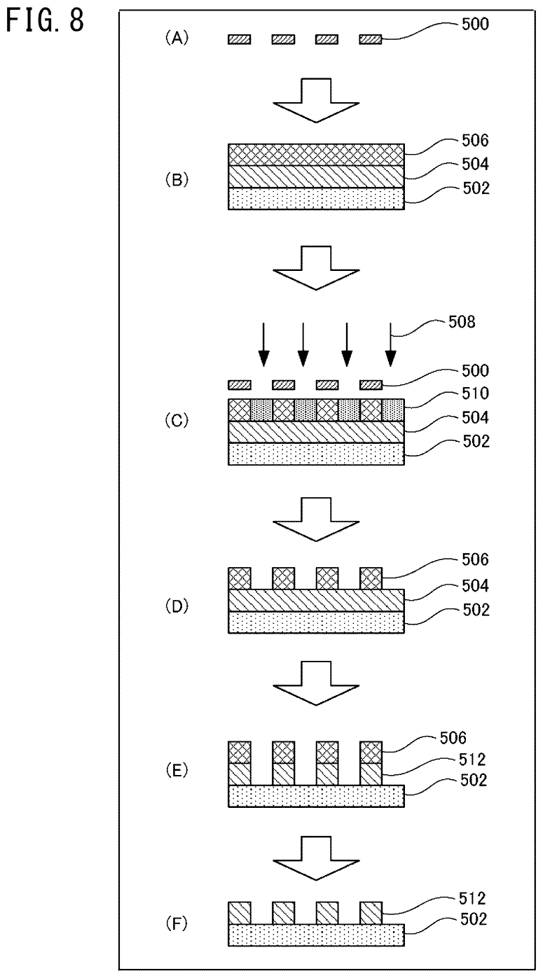

A method for producing the high-speed transmission boards 150 each shown in FIG. 6 in a state in which they are arranged as shown in FIG. 7 will be described. With reference to FIG. 8, in step (A), a pattern is formed on a glass substrate or the like, to produce a photomask 500. Specifically, the photomask 500 is formed so that the high-speed transmission boards 172 to 176 are formed on the panel 170 as shown in FIG. 7. That is, the photomask 500 has patterns corresponding to the high-speed transmission paths 152A to 152D. Around each of the patterns of the photomask 500 corresponding to the high-speed transmission paths 152A to 152D, a light blocking portion (hereinafter, referred to as mask portion) is provided in a case of using a positive photoresist, or a mask portion is not provided in a case of using a negative photoresist, so that a copper foil uniformly remains after etching.

Subsequently, in step (B), a photoresist 506 is formed by, for example, application, on a panel having a copper foil 504 formed on a substrate 502. The photoresist 506 is a positive type. Subsequently, in step (C), the photomask 500 is placed above the substrate that has undergone step (B), and light 508, such as UV light, for altering the photoresist 506 is applied. An altered part of the photoresist 506 irradiated with the light 508 is shown as an altered photoresist 510. Subsequently, in step (D), the photomask 500 is removed, and the altered photoresist 510 altered in step (C) is removed by, for example, an alkali solution. Thus, on the copper foil 504, the photoresist 506 remains at parts corresponding to the patterns of the photomask and uniformly around the patterns.

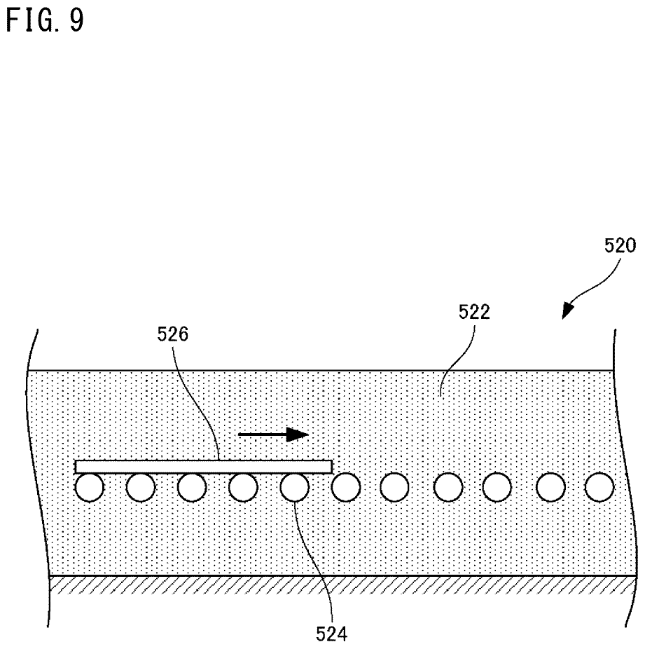

Subsequently, in step (E), the copper foil 504 is etched using an etching solution. Specifically, with reference to FIG. 9, a panel 526 which is the substrate after step (D) is placed on rollers 524 in an etching tank 520 and is moved in an arrow orientation (i.e., rightward) in an etching solution 522. The rightward arrow orientation in FIG. 9 corresponds to the downward arrow orientation shown in FIG. 7. The copper foil 504 remaining after the etching is shown as a residual copper foil 512. Subsequently, in step (F), the remaining photoresist 506 is removed and washing is performed. Then, each high-speed transmission board is cut. Thus, four high-speed transmission boards 150 each shown in FIG. 6 are produced from one panel.

As described above, wet etching can be performed in a state in which the photoresist for causing the copper foil to remain is uniformly left around each of the high-speed transmission paths 152A to 152D shown in FIG. 7 and an etching solution flows along each of the high-speed transmission paths 152A to 152D. Thus, the etching speeds at parts where respective high-speed transmission paths are formed can be made uniform, and variations from a design value, in the impedances of high-speed transmission paths included in a plurality of high-speed transmission boards produced from one panel, can be suppressed.

In the above description, the case where the photoresist is a positive type has been described, but the photoresist type is not limited thereto. A negative photoresist may be used. In this case, a photomask configured by reversing a light transmitting part and a light blocking part with each other in the photomask for the positive photoresist may be used. In addition, after light exposure, the non-exposed photoresist may be removed using an organic solvent or the like.

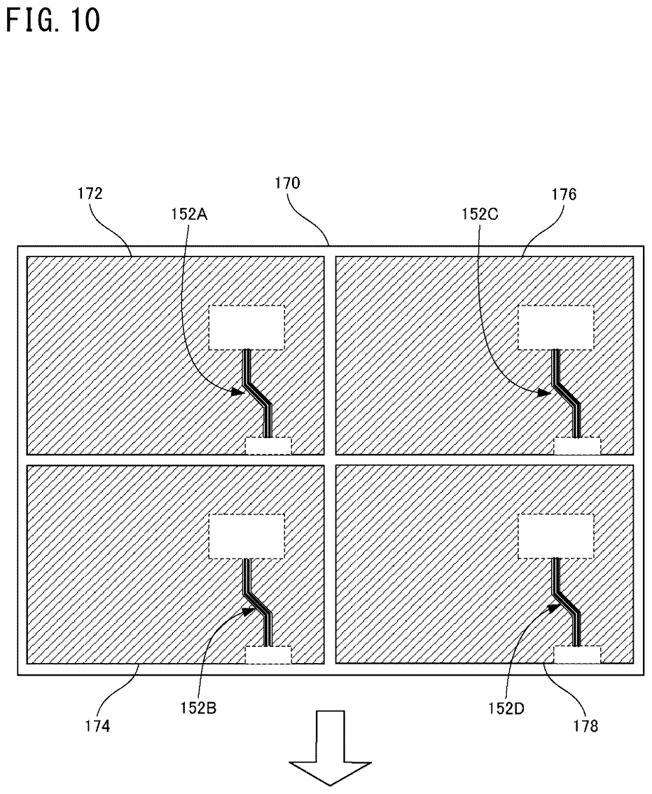

Instead of arranging four boards as shown in FIG. 7, each of the high-speed transmission board 176 and the high-speed transmission board 178 shown in FIG. 7 may be rotated by 180 degrees so that the high-speed transmission board 176 and the high-speed transmission board 178 are formed in the same orientation (i.e., translational symmetry) as the high-speed transmission board 172 and the high-speed transmission board 174, as shown in FIG. 10. However, in this case, the high-speed transmission path 152C and the high-speed transmission path 152D on the high-speed transmission board 176 and the high-speed transmission board 178 formed in the right area of the panel 170 are closer to the right side than to the center of the panel 170, and thus an area where a copper foil is uniformly present is not present over a sufficient range at the right of the high-speed transmission path 152C and the high-speed transmission path 152D. Therefore, variations in the impedances of the high-speed transmission paths 152A to 152D are greater in the arrangement shown in FIG. 10 than in the arrangement shown in FIG. 7.

If the panel 170 shown in FIG. 7 is vertically long, high-speed transmission boards having the same specifications as the high-speed transmission board 174 and the high-speed transmission board 178 may be repeatedly formed on the lower side of the high-speed transmission board 174 and the high-speed transmission board 178. Thus, regarding the high-speed transmission board 150 shown in FIG. 6, more high-speed transmission boards, e.g., six or eight high-speed transmission boards, can be produced from one panel.

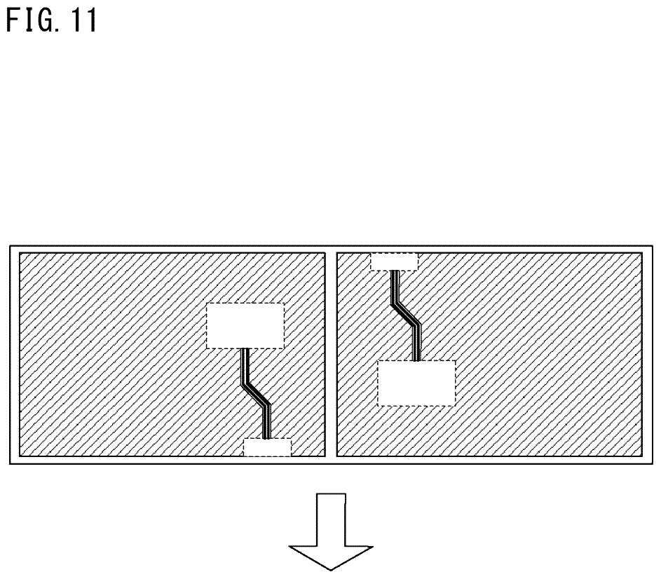

With reference to FIG. 11, two high-speed transmission boards 150 each shown in FIG. 6 may be produced from one panel. Also in this case, it is preferable that the high-speed transmission paths included in the respective high-speed transmission boards are arranged at 2-fold rotational symmetry positions closely to each other and the panel is moved in an etching solution in the direction of the high-speed transmission paths (i.e., an orientation indicated by an arrow in FIG. 11 and an orientation opposite thereto).

In the wet etching process, there are two arbitrary options for the flow orientation of the rectangular panel, i.e., the orientation in which the panel is moved in an etching solution. Therefore, the flow orientation may be fixed in accordance with the panel size. In this case, a photomask having patterns corresponding to high-speed transmission paths may be used so that the respective high-speed transmission paths formed on the panel are along the panel moving orientation. The flow orientation may be designated on the specifications in board production. On each of the produced high-speed transmission boards, a figure (e.g., arrow) or the like indicating the flow orientation may be formed by screen printing or the like. If the flow orientation is known, it is possible to manage the high-speed transmission boards after production.

### First Modification

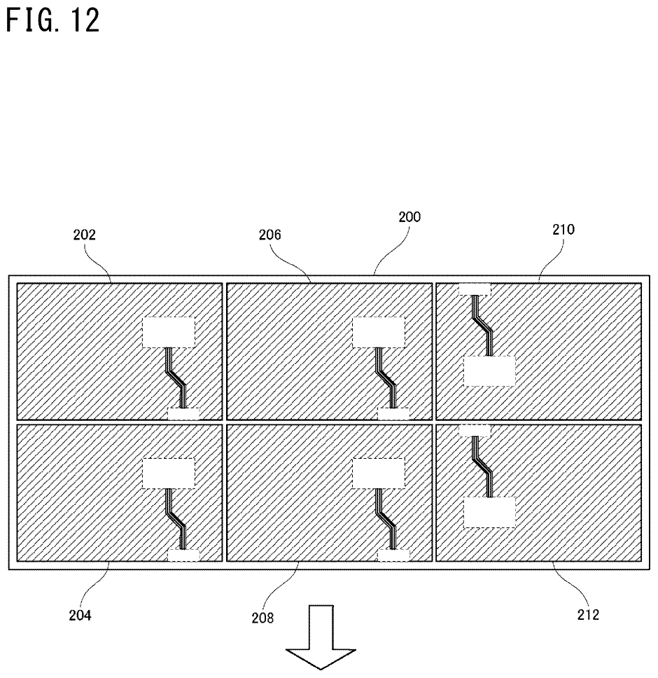

In the above description, the case where four high-speed transmission boards 150 each shown in FIG. 6 are produced from one panel has been described, but the number thereof is not limited thereto. In a first modification, as shown in FIG. 12, six high-speed transmission boards 150 each shown in FIG. 6 are produced from one panel. That is, in wet etching, a panel 200 is moved in an etching solution in an orientation indicated by a downward arrow, whereby six high-speed transmission boards 150 (i.e., high-speed transmission boards 202 to 212) are produced from one panel 200. In FIG. 12, hatched areas represent parts where copper foils remain after wet etching. The high-speed transmission boards 202 to 208 are formed in the same orientation (i.e., translational symmetry) as the high-speed transmission board 150, and the high-speed transmission board 210 and the high-speed transmission board 212 are formed in an orientation rotated by 180 degrees from the high-speed transmission board 150. That is, as in FIG. 7, high-speed transmission paths formed on the high-speed transmission board 206 and the high-speed transmission board 210 arranged in a direction perpendicular to the flow orientation of wet etching are arranged in a 2-fold rotational symmetry form closely to each other. Similarly, high-speed transmission paths formed on the high-speed transmission board 208 and the high-speed transmission board 212 are arranged in a 2-fold rotational symmetry form closely to each other.

Thus, by performing the production method shown in FIG. 8 using a photomask for forming the high-speed transmission boards 202 to 212, a state in which a copper foil is uniformly present around each high-speed transmission path can be realized in wet etching. That is, in a state in which a copper foil is uniformly present around each high-speed transmission path shown in FIG. 12, an etching solution flows along each high-speed transmission path, so that wet etching is performed. Thus, the etching speeds at parts where respective high-speed transmission paths are formed can be made uniform, and variations from a design value with respect to the impedances of high-speed transmission paths included in a plurality of high-speed transmission boards produced from one panel, can be suppressed.

If the panel 200 shown in FIG. 12 is vertically long, high-speed transmission boards having the same specifications as the high-speed transmission board 204, the high-speed transmission board 208, and the high-speed transmission board 212 may be repeatedly formed on the lower side of the high-speed transmission board 204, the high-speed transmission board 208, and the high-speed transmission board 212. Thus, regarding the high-speed transmission board 150 shown in FIG. 6, more high-speed transmission boards, e.g., nine or twelve high-speed transmission boards, can be produced from one panel.

### Second Modification

In a case where a plurality of high-speed transmission boards 150 each shown in FIG. 6 are produced from one panel, a part where the high-speed transmission board 150 is not formed and which is discarded (hereinafter, referred to as disposal portion) might be produced. In a second modification, even in such a case, a plurality of high-speed transmission boards including high-speed transmission paths having impedances in which variations are small can be produced from one panel.

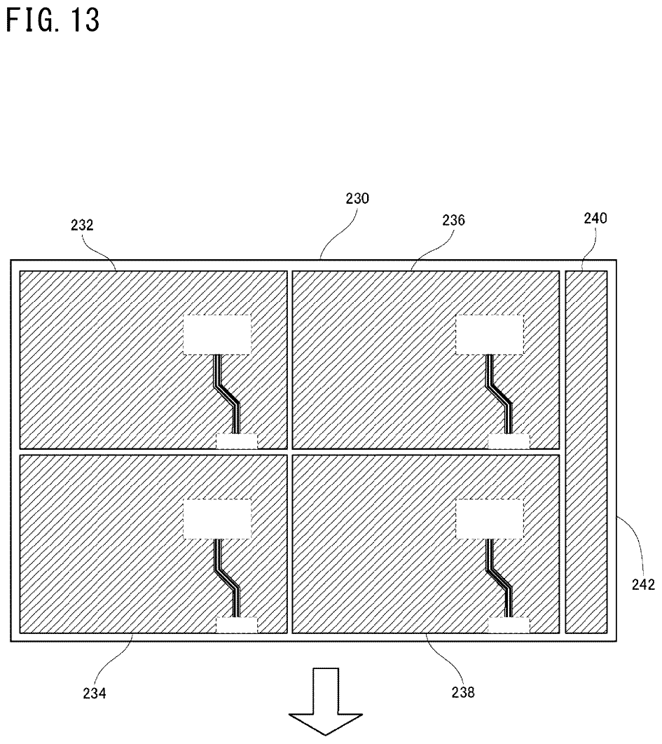

With reference to FIG. 13, in wet etching, a panel 230 is moved in an etching solution in an orientation indicated by a downward arrow, whereby four high-speed transmission boards 150 (i.e., high-speed transmission boards 232 to 238) are produced from one panel 230. In FIG. 13, hatched areas represent parts where copper foils remain after wet etching. The high-speed transmission boards 232 to 238 are all formed in the same orientation (i.e., translational symmetry) as the high-speed transmission board 150. A disposal portion 240 is formed in a range of a predetermined distance from a part of the outer periphery of the panel 230, i.e., a right side 242.

By performing the production method shown in FIG. 8 using a photomask for forming the high-speed transmission boards 232 to 238 and the disposal portion 240, a state in which copper foils are uniformly present also around high-speed transmission paths formed on the high-speed transmission board 236 and the high-speed transmission board 238 can be realized owing to the disposal portion 240, in wet etching. That is, in a state in which a copper foil is uniformly present around each high-speed transmission path shown in FIG. 13, an etching solution flows along each high-speed transmission path, so that wet etching is performed. Thus, the etching speeds at parts where respective high-speed transmission paths are formed can be made uniform, and variations from a design value with respect to the impedances of high-speed transmission paths included in a plurality of high-speed transmission boards produced from one panel, can be suppressed.

It is preferable that the width (i.e., the length in a direction perpendicular to the right side 242) of the disposal portion 240 is not less than 2 cm. Thus, variations in the impedances of high-speed transmission paths can be more suppressed even in a case where the high-speed transmission paths formed on the high-speed transmission board 236 and the high-speed transmission board 238 adjacent to the disposal portion 240 are closer to the right sides of the respective high-speed transmission boards.

If the panel 230 shown in FIG. 13 is vertically long, high-speed transmission boards having the same specifications as the high-speed transmission board 234 and the high-speed transmission board 238 may be repeatedly formed on the lower side of the high-speed transmission board 234 and the high-speed transmission board 238. Thus, regarding the high-speed transmission board 150 shown in FIG. 6, more high-speed transmission boards, e.g., six or eight high-speed transmission boards, can be produced from one panel.

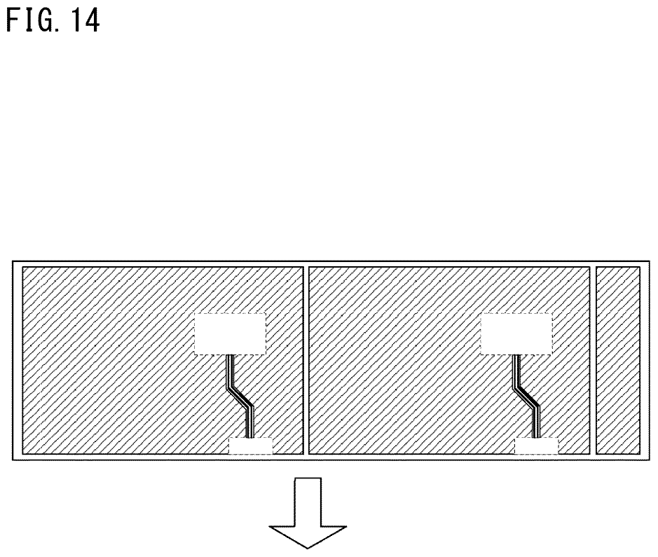

As shown in FIG. 14, two high-speed transmission boards 150 each shown in FIG. 6 may be produced from one panel. In this case, it is preferable that a disposal portion is located adjacently to a high-speed transmission path included in one high-speed transmission board (i.e., a high-speed transmission board at the right in FIG. 14), and the panel is moved in an etching solution in the direction of the high-speed transmission paths (i.e., an orientation indicated by an arrow in FIG. 14 and an orientation opposite thereto).

### Third Modification

A plurality of disposal portions may be included in one panel. In a third modification, even in such a case, a plurality of high-speed transmission boards including high-speed transmission paths having impedances in which variations are small can be produced from one panel.

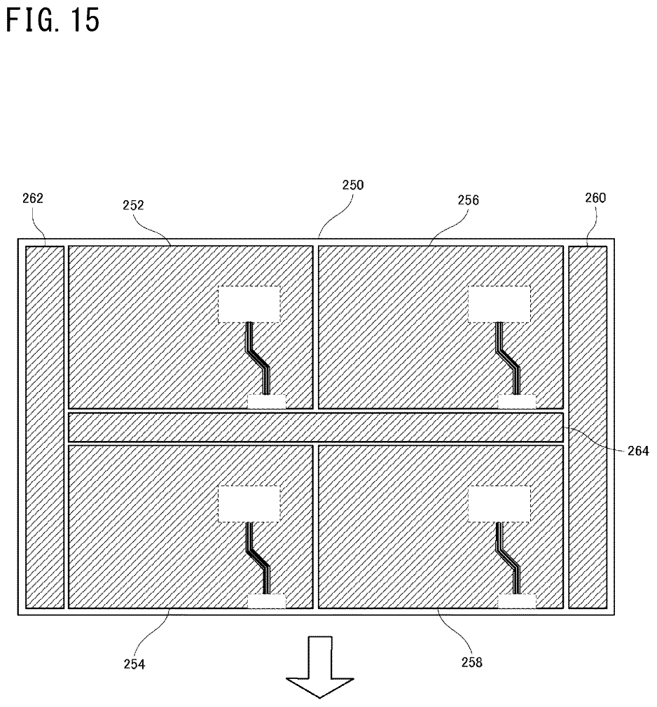

With reference to FIG. 15, in wet etching, a panel 250 is moved in an etching solution in an orientation indicated by a downward arrow, whereby four high-speed transmission boards 150 (i.e., high-speed transmission boards 252 to 258) each shown in FIG. 6 are produced from one panel 250. In FIG. 15, hatched areas represent parts where copper foils remain after wet etching. The high-speed transmission boards 252 to 258 are all formed in the same orientation (i.e., translational symmetry) as the high-speed transmission board 150. A disposal portion 260 and a disposal portion 262 are formed in ranges of predetermined distances from parts of the outer periphery of the panel 250 (specifically, right side and left side). In addition, a disposal portion 264 is formed so as to include a central part of the panel 250. Then, a photomask is formed so that copper foils remain also in the disposal portions 260 to 264 which are areas other than the high-speed transmission boards 252 to 258 on the panel 250, and the production method shown in FIG. 8 is performed. Thus, a state in which a copper foil is uniformly present around each high-speed transmission path can be realized in wet etching.

Thus, in a state in which a photoresist for causing a copper foil to remain is uniformly present around each high-speed transmission path shown in FIG. 15, an etching solution flows along each high-speed transmission path, so that wet etching is performed. Thus, the etching speeds at parts where respective high-speed transmission paths are formed can be made uniform, and variations from a design value, in the impedances of high-speed transmission paths included in a plurality of high-speed transmission boards produced from one panel, can be suppressed.

### Fourth Modification

In the above description, the case of producing the high-speed transmission board 150 on which a copper foil is present around the high-speed transmission path 152 as shown in FIG. 6 has been described, but the present disclosure is not limited thereto. In a fourth modification, a high-speed transmission board on which a copper foil is absent around a high-speed transmission path is to be produced.

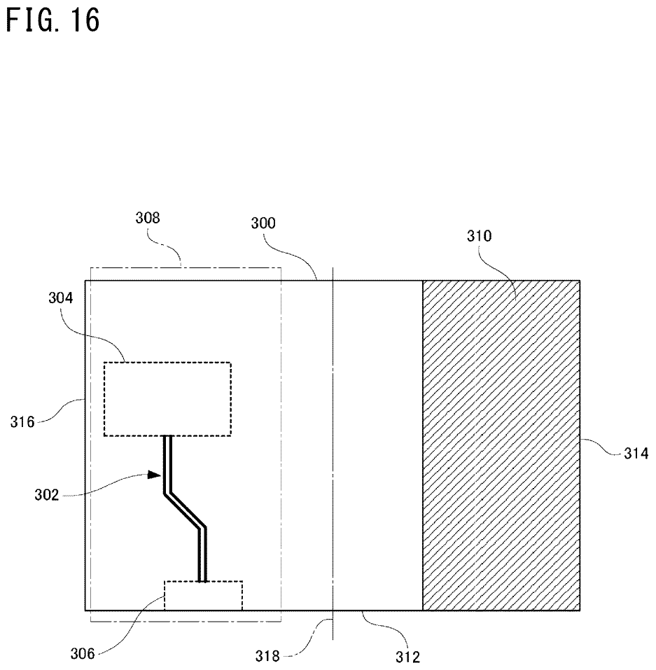

With reference to FIG. 16, a high-speed transmission board 300 includes a high-speed transmission path 302, a chip mounting area 304, a connector mounting area 306, and a copper foil area 310. The high-speed transmission board 300 is formed by performing wet etching at a copper foil formed on a flat plate of resin or the like. The high-speed transmission path 302 is a wire for connecting a semiconductor element and a connector placed together on the high-speed transmission board 300 and transmitting a high-frequency signal of 1 GHz or higher. In FIG. 16, the chip mounting area 304 is located away from the outer periphery (i.e., four sides) of the high-speed transmission board 300, and the connector mounting area 306 is located adjoining a part (specifically, a lower side 312) of the outer periphery of the high-speed transmission board 300. Arrangement of the chip mounting area 304 and the connector mounting area 306 is not limited to that shown in FIG. 16. The high-speed transmission path 302 is formed of two wires and transmits differential signals. In the drawing, wire patterns are not shown in the chip mounting area 304 and the connector mounting area 306, but wire patterns corresponding to terminals of the semiconductor element and the connector mounted in the respective areas are formed. The wire patterns formed in the chip mounting area 304 and the connector mounting area 306 also include wire patterns connected to the high-speed transmission path 302.

The high-speed transmission path 302, the chip mounting area 304, and the connector mounting area 306 are arranged so as to be decentered in a predetermined orientation from the center of the high-speed transmission board 300. That is, the high-speed transmission path 302, the chip mounting area 304, and the connector mounting area 306 are arranged in a first area 308 located at the left of a center line 318 of the high-speed transmission board 300 perpendicular to the lower side 312. Thus, the semiconductor element and the connector respectively mounted in the chip mounting area 304 and the connector mounting area 306 are also arranged at positions decentered in a predetermined orientation from the center of the high-speed transmission board 300. The direction of the high-speed transmission path 302 (i.e., upward and downward orientations in FIG. 16) is along a left side 316. The copper foil area 310 is an area (i.e., second area) where a copper foil remains in a predetermined range from a right side 314 after wet etching, and is located on a side opposite to the first area 308 across the center line 318.

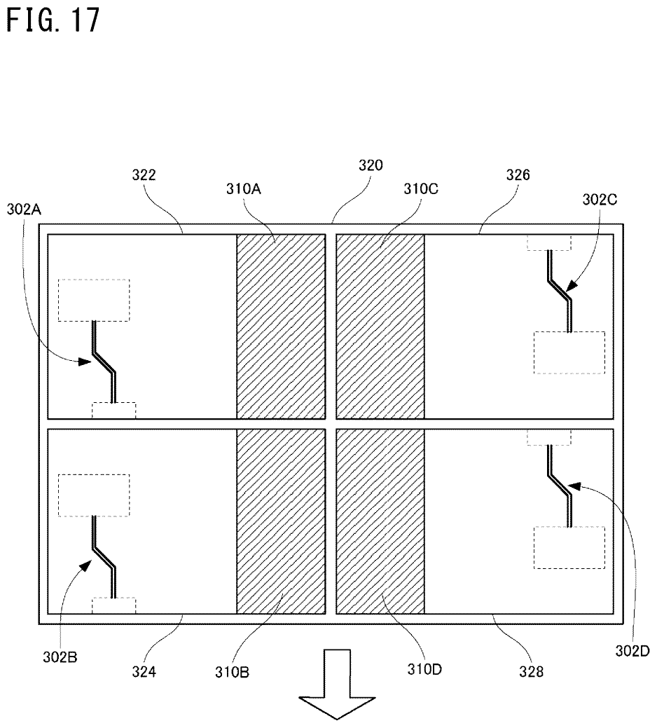

Using one panel, a plurality of the high-speed transmission boards 300 can be produced. With reference to FIG. 17, using one panel 320, in wet etching, the panel 320 is moved in an etching solution in an orientation indicated by a downward arrow, whereby four high-speed transmission boards 300 (i.e., high-speed transmission boards 322 to 328) are produced. In FIG. 17, hatched areas represent parts where copper foils remain after the wet etching. The high-speed transmission board 322 and the high-speed transmission board 324 are formed in the same orientation (i.e., translational symmetry) as the high-speed transmission board 300, and the high-speed transmission board 326 and the high-speed transmission board 328 are formed in a state in which the high-speed transmission board 300 is rotated by 180 degrees. That is, regarding the high-speed transmission board 322 and the high-speed transmission board 326 arranged in a direction perpendicular to the flow orientation of the wet etching, a high-speed transmission path 302A and a high-speed transmission path 302C are arranged in a 2-fold rotational symmetry form away from each other (i.e., closer to both of left and right ends than to the center of the panel 320). Similarly, a high-speed transmission path 302B formed on the high-speed transmission board 324 and a high-speed transmission path 302D formed on the high-speed transmission board 328 are arranged in a 2-fold rotational symmetry form away from each other. Thus, copper foil areas 310A to 310D are concentrated at the center of the panel 320.

Thus, by performing the production method shown in FIG. 8 using a photomask for forming the high-speed transmission boards 322 to 328, a state in which a photoresist for causing a copper foil to remain is uniformly absent around each of the high-speed transmission paths 302A to 302D (i.e., a state in which absence is uniform) can be realized in wet etching. That is, an etching solution flows along each high-speed transmission path and wet etching is performed so that a copper foil is uniformly absent around each high-speed transmission path shown in FIG. 17. Thus, the etching speeds at parts where respective high-speed transmission paths are formed can be made uniform, and variations from a design value, in the impedances of high-speed transmission paths included in a plurality of high-speed transmission boards produced from one panel, can be suppressed.

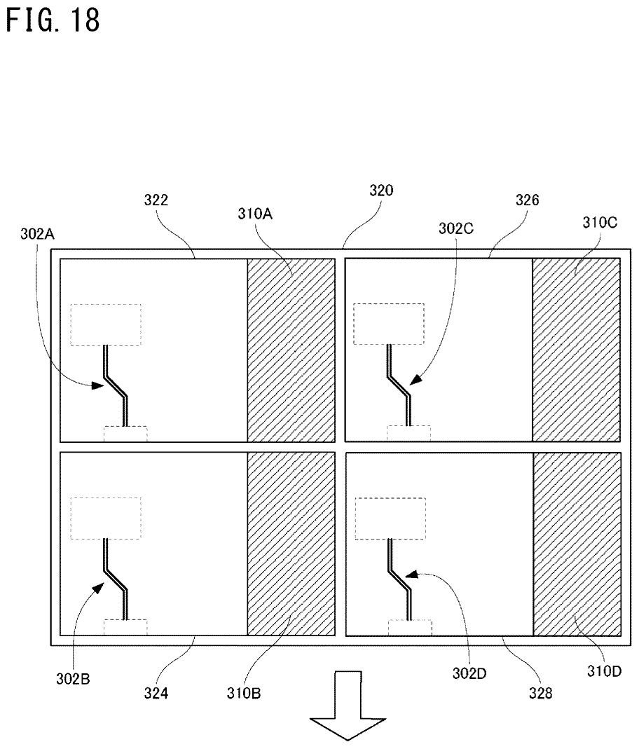

Instead of forming four boards on one panel as shown in FIG. 17, each of the high-speed transmission board 326 and the high-speed transmission board 328 may be rotated by 180 degrees so that the high-speed transmission board 326 and the high-speed transmission board 328 are formed in the same orientation (i.e., translational symmetry) as the high-speed transmission board 322 and the high-speed transmission board 324, as shown in FIG. 18. However, in this case, the high-speed transmission path 302C and the high-speed transmission path 302D of the high-speed transmission board 326 and the high-speed transmission board 328 formed in the right area of the panel 320 are located closer to the copper foil area 310A and the copper foil area 310B than to the right side of the panel 320, and thus an area where a copper foil is uniformly absent is not present over a sufficient range at the left of the high-speed transmission path 302C and the high-speed transmission path 302D. Therefore, variations in the impedances of the high-speed transmission paths 302A to 302D are greater in the arrangement shown in FIG. 18 than in the arrangement shown in FIG. 17.

If the panel 320 shown in FIG. 17 is vertically long, high-speed transmission boards having the same specifications as the high-speed transmission board 324 and the high-speed transmission board 328 may be repeatedly formed on the lower side of the high-speed transmission board 324 and the high-speed transmission board 328. Thus, regarding the high-speed transmission board 300 shown in FIG. 16, more high-speed transmission boards, e.g., six or eight high-speed transmission boards, can be produced from one panel.

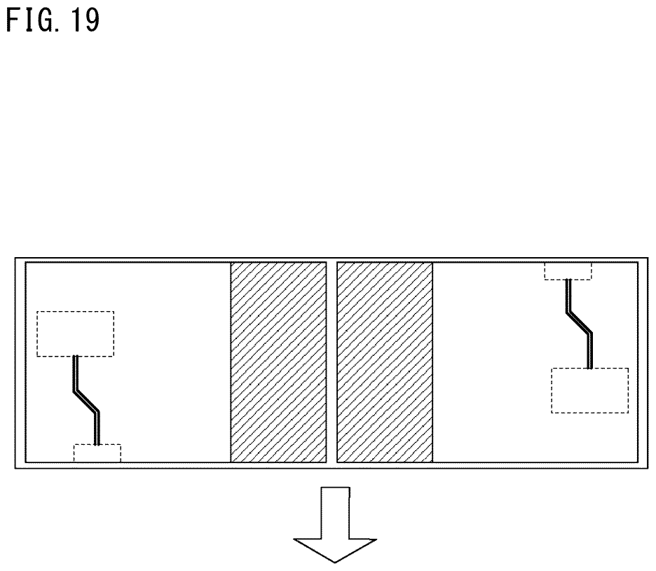

With reference to FIG. 19, two high-speed transmission boards 300 each shown in FIG. 16 may be produced from one panel. In this case, it is preferable that the high-speed transmission paths included in the respective high-speed transmission boards are arranged at 2-fold rotational symmetry positions away from each other (i.e., the copper foil areas 310 are arranged closely to each other and the panel is moved in an etching solution in the direction of the high-speed transmission paths (i.e., an orientation indicated by an arrow in FIG. 19 and an orientation opposite thereto).

A predetermined area where presence/absence of a copper foil should be made uniform around each high-speed transmission path in order to suppress variations in the impedances of high-speed transmission paths can be appropriately determined, considering the result of the preliminary experiment described above, in accordance with the sizes of high-speed transmission boards and high-speed transmission paths. Therefore, in accordance with the above, a predetermined area where a mask portion is formed or not formed around a pattern corresponding to a high-speed transmission path on a photomask, is determined. Regarding interpretation of the predetermined area, an area essential for causing a wire to function as a high-speed transmission path is included in a high-speed transmission path. That is, an area (hereinafter, referred to as first essential area) essential for making two wires away from each other, and in a case of placing a copper foil around a high-speed transmission path, an area (hereinafter, referred to as second essential area) essential for making two wires away from a surrounding copper foil, are not included in the predetermined area. The first essential area is, for example, an area where a copper foil is absent between two wires forming the high-speed transmission path 152 shown in FIG. 6. The second essential area is, for example, an area where a copper foil is absent on both sides of the high-speed transmission path 152 shown in FIG. 6. When it is described that a copper foil is uniformly present in the predetermined area around a high-speed transmission path, the high-speed transmission path is interpreted as including not only two wires but also the first essential area and the second essential area. In addition, the predetermined area where a copper foil is uniformly present may include a narrow-width area where a copper foil is absent, which is provided for separating a plurality of high-speed transmission boards from each other on the panel. For example, in FIG. 7, a cross area where a copper foil is absent, for separating the high-speed transmission boards 172 to 178 from each other, is shown. Also in this case, it is described that a copper foil is uniformly present in the predetermined area around the high-speed transmission path on the panel.

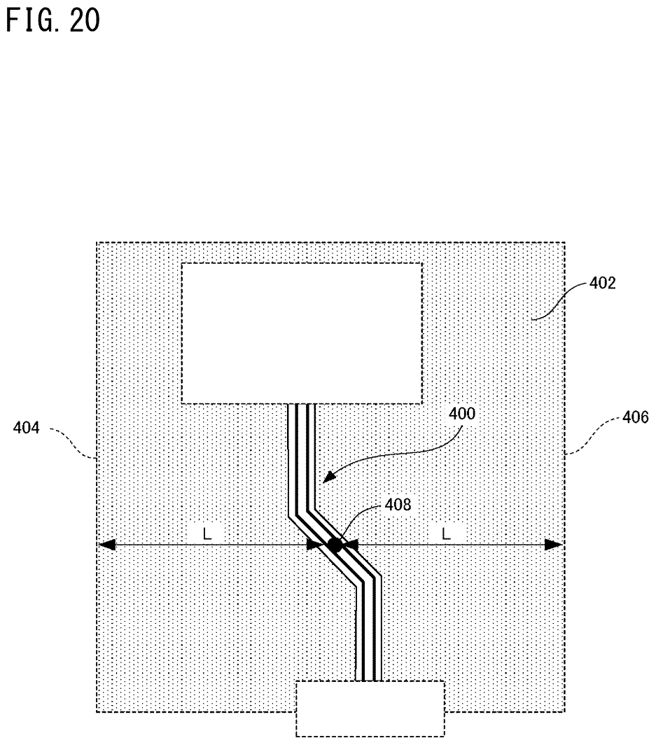

For example, with reference to FIG. 20, it is preferable that the distance between a pattern 400 corresponding to a high-speed transmission path and each of an outer edge 404 and an outer edge 406 along the pattern 400 among outer edges of a predetermined area 402 (i.e., four sides of the predetermined area 402) on a photomask, is not less than 4 cm. The distance between the pattern 400 and each of the outer edge 404 and the outer edge 406 is, to be exact, a distance L to a geometric center 408 of the pattern 400. That is, L≥4 (cm) is preferable. The lengths of the outer edge 404 and the outer edge 406 along the pattern 400 only have to be greater than the length of the pattern 400 (i.e., the size in the direction along the pattern 400). Thus, when the panel undergoes wet etching, the etching speeds at parts where respective high-speed transmission paths are formed can be made more uniform and variations in the impedances of high-speed transmission paths can be more suppressed. The shape of the pattern 400 corresponds to a high-speed transmission path, and can be changed in accordance with the shape of the high-speed transmission path, without being limited to that shown in FIG. 20.

More preferably, the distance between the pattern 400 and each of the outer edge 404 and the outer edge 406 along the pattern 400 (to be exact, the distance L to the geometric center 408) is not less than 6 cm (L≥6 (cm)). Thus, when the panel undergoes wet etching, the etching speeds at parts where respective high-speed transmission paths are formed can be made even more uniform and variations in the impedances of high-speed transmission paths can be even more suppressed.

Even more preferably, the distance between the pattern 400 and each of the outer edge 404 and the outer edge 406 along the pattern 400 (to be exact, the distance L to the geometric center 408) is not less than 12 cm (L≥12 (cm)). Thus, when the panel undergoes wet etching, the etching speeds at parts where respective high-speed transmission paths are formed can be made still even more uniform and variations in the impedances of high-speed transmission paths can be still even more suppressed.

In the above description, the case where the high-speed transmission path is formed by two wires for transmitting differential signals has been described. However, the present disclosure is not limited thereto. The high-speed transmission path may have a configuration (i.e., single end) in which a signal is transmitted through one wire (using, for example, the ground as a reference level). For example, the high-speed transmission path may be an antenna. The antenna can be formed by one wire, for example. Normally, a copper foil is not formed around the antenna. In a case where a plurality of high-speed transmission boards including antennas are produced from one panel, for example, by forming a plurality of high-speed transmission boards as shown in FIG. 17, variations in the impedances of the antennas can be suppressed.

In the above description, the case of moving the panel in an etching solution in wet etching has been described. However, the present disclosure is not limited thereto. An etching solution may flow while the panel is fixed. As long as the flowing orientation of the etching solution is along the high-speed transmission paths to be formed on the panel, the etching speeds can be made uniform and variations in the impedances of high-speed transmission paths can be suppressed as described above.

In the above description, the case where the design value for the impedances of the high-speed transmission paths is 100Ω has been described. However, the present disclosure is not limited thereto. The design value for the impedances of the high-speed transmission paths are arbitrary, and may be 75Ω or 50Ω, for example.

In the above description, the case where the high-speed transmission board and the panel have rectangular shapes has been described. However, the present disclosure is not limited thereto. The high-frequency board and the panel may have any shapes. In any case, it suffices that the photomask is formed so that respective high-speed transmission paths to be formed on the panel are along each other and copper foils remain or are removed around the high-speed transmission paths such that a part where a copper foil remains and a part where a copper foil does not remain are not mixed.

In the above description, the production method for a high-speed transmission board has been described. However, the present disclosure is not limited thereto. A transmission board including a wire for transmitting a signal having a frequency lower than 1 GHz may be produced. The present disclosure is applicable to production of such transmission boards that wire dimensional accuracy influences variations in the impedances.

While the present disclosure has been described through description of the embodiment above, the above embodiment is merely illustrative and the present disclosure is not limited to only the above embodiment. The scope of the present disclosure is defined by each claim of the scope of claims with reference to the above description, and includes meanings equivalent to the wordings described therein and all modifications within the scope of claims.

### REFERENCE SIGNS LIST

100 dielectric member
102, 104, 106, 108 conductive member
110, 110A, 110B, 110C, 110D, 110E, 110F, 110G, 110H test coupon
112, 114 wire
116 board
120, 122, 124, 126 terminal portion
130, 170, 200, 230, 250, 320, 526 panel
132 copper foil area
134 resin area
150, 172, 174, 176, 178, 202, 204, 206, 208, 210, 212, 232, 234, 236, 238, 252, 254, 256, 258, 300, 322, 324, 326, 328 high-speed transmission board
152, 152A, 152B, 152C, 152D, 302, 302A, 302B, 302C, 302D high-speed transmission path
154, 304 chip mounting area
156, 306 connector mounting area
158, 308 first area
160, 312 lower side
162, 242, 314 right side
164, 318 center line
240, 260, 262, 264 disposal portion
310, 310A, 310B, 310C, 310D copper foil area
316 left side
400 pattern
402 predetermined area
404, 406 outer edge
408 geometric center
500 photomask
502 substrate
504 copper foil (i.e., member to be etched)
506 photoresist
508 light
510 altered photoresist
512 residual copper foil
520 etching tank
522 etching solution
524 roller
(A), (B), (C), (D), (E), (F) step
A1, A2, A3, A4, A5 area
H height
L, S distance
T thickness
W width

1. A transmission board production method for producing a plurality of transmission boards from a panel having a copper foil on a surface thereof, the plurality of transmission boards each including a transmission path, the transmission board production method comprising:
a resist formation step of forming a photoresist on the copper foil;
an exposure step of irradiating the photoresist with light via a photomask;
a resist removal step of removing, of the photoresist, either of a part irradiated with the light and a part not irradiated with the light; and
an etching step of performing wet etching at a part, of the copper foil, exposed through the resist removal step, using an etching solution, wherein
the photomask includes a pattern for forming the transmission path included in each of the plurality of transmission boards, so that the transmission paths are along each other,
the photomask is formed so that, of the copper foil, a part around each of a plurality of the transmission paths to be formed through the etching step is removed or remains such that a part where the copper foil remains and a part where the copper foil does not remain are not mixed, through the etching step, and
in the etching step, the etching solution moves relative to the panel along each transmission path to be formed through the etching step.

2. The transmission board production method according to claim 1, wherein
the transmission path includes a first connection portion to which a semiconductor element is connected, and a second connection portion to which a connector is connected,
the transmission path, the first connection portion, and the second connection portion are arranged so as to be decentered in a predetermined orientation from a center of the transmission board,
at least two said transmission boards are produced from the panel,
the photomask is formed so that, of the copper foil, a part around each of a plurality of the transmission paths to be formed through the etching step remains such that a part where the copper foil remains and a part where the copper foil does not remain are not mixed, through the etching step, and
in the photomask, at least a pair of the patterns are arranged at 2-fold rotational symmetry positions closely to each other.

3. The transmission board production method according to claim 1, wherein
the transmission path includes a first connection portion to which a semiconductor element is connected, and a second connection portion to which a connector is connected,
the transmission path, the first connection portion, and the second connection portion are arranged in a first area adjacent to an outer periphery of the transmission board, so as to be decentered in a predetermined orientation from a center of the transmission board,
the photomask is formed so that, of the copper foil, a part around each of a plurality of the transmission paths to be formed through the etching step remains such that a part where the copper foil remains and a part where the copper foil does not remain are not mixed, through the etching step,
the panel includes a disposal portion which is a part in a range of a predetermined distance from an outer periphery of the panel and which does not form the transmission board,
the disposal portion is located adjacently to the first area of at least one of the transmission boards, and
the copper foil remains on the disposal portion, after the etching step.

4. The transmission board production method according to claim 3, wherein
the predetermined distance is not less than 2 cm.

5. The transmission board production method according to claim 1, wherein
the transmission path includes a first connection portion to which a semiconductor element is connected, and a second connection portion to which a connector is connected,
the transmission path, the first connection portion, and the second connection portion are arranged in a first area so as to be decentered in a predetermined orientation from a center of the transmission board,
the transmission board includes a second area where the copper foil remains after the etching step,
the second area is located on a side opposite to the first area across a center of the transmission board,
at least two said transmission boards are produced from the panel,
the photomask is formed so that, of the copper foil, a part around each of a plurality of the transmission paths to be formed through the etching step is removed such that a part where the copper foil remains and a part where the copper foil does not remain are not mixed, through the etching step, and
in the photomask, at least a pair of the patterns are arranged at 2-fold rotational symmetry positions away from each other.

6. The transmission board production method according to claim 1, wherein
the transmission path is an antenna.

7. The transmission board production method according to claim 1, wherein
the photomask includes, for each of a plurality of the patterns, a predetermined area for forming, of the copper foil, a part to be removed or remain such that a part where the copper foil remains and a part where the copper foil does not remain are not mixed, through the etching step, and
of outer edges of the predetermined area, a predetermined outer edge along the pattern is away from the pattern by 4 cm or more.

8. The transmission board production method according to claim 7, wherein
for each of a plurality of the patterns, the predetermined outer edge is away from the pattern by 6 cm or more.

9. The transmission board production method according to claim 8, wherein
for each of a plurality of the patterns, the predetermined outer edge is away from the pattern by 12 cm or more.

10. The transmission board production method according to claim 2, wherein
the photomask includes, for each of a plurality of the patterns, a predetermined area for forming, of the copper foil, a part to be removed or remain such that a part where the copper foil remains and a part where the copper foil does not remain are not mixed, through the etching step, and
of outer edges of the predetermined area, a predetermined outer edge along the pattern is away from the pattern by 4 cm or more.

11. The transmission board production method according to claim 3, wherein
the photomask includes, for each of a plurality of the patterns, a predetermined area for forming, of the copper foil, a part to be removed or remain such that a part where the copper foil remains and a part where the copper foil does not remain are not mixed, through the etching step, and
of outer edges of the predetermined area, a predetermined outer edge along the pattern is away from the pattern by 4 cm or more.

12. The transmission board production method according to claim 4, wherein
the photomask includes, for each of a plurality of the patterns, a predetermined area for forming, of the copper foil, a part to be removed or remain such that a part where the copper foil remains and a part where the copper foil does not remain are not mixed, through the etching step, and
of outer edges of the predetermined area, a predetermined outer edge along the pattern is away from the pattern by 4 cm or more.

13. The transmission board production method according to claim 5, wherein
the photomask includes, for each of a plurality of the patterns, a predetermined area for forming, of the copper foil, a part to be removed or remain such that a part where the copper foil remains and a part where the copper foil does not remain are not mixed, through the etching step, and
of outer edges of the predetermined area, a predetermined outer edge along the pattern is away from the pattern by 4 cm or more.

14. The transmission board production method according to claim 6, wherein
the photomask includes, for each of a plurality of the patterns, a predetermined area for forming, of the copper foil, a part to be removed or remain such that a part where the copper foil remains and a part where the copper foil does not remain are not mixed, through the etching step, and
of outer edges of the predetermined area, a predetermined outer edge along the pattern is away from the pattern by 4 cm or more.

15. The transmission board production method according to claim 2, wherein
the predetermined orientation is perpendicular to a direction in which the etching solution moves in the etching step,
in the photomask, the pair of the patterns are arranged so as to oppose each other in the predetermined orientations in a state in which outer sides in the predetermined orientations of the pair of the patterns are both sandwiched between parts where the copper foils remain.

16. The transmission board production method according to claim 5, wherein
the predetermined orientation is perpendicular to a direction in which the etching solution moves in the etching step,
in the photomask, the pair of the patterns are arranged with the predetermined orientations directed against each other in a state in which outer sides in the predetermined orientations of the second areas opposing each other are both sandwiched between parts where the copper foils do not remain.

17. The transmission board production method according to claim 1, wherein
the transmission path includes a first connection portion to which a semiconductor element is connected, and a second connection portion to which a connector is connected, and
a direction in which the transmission path extends has a component parallel to a direction in which the etching solution moves, over an entire range from the first connection portion to the second connection portion.

18. The transmission board production method according to claim 1, wherein
a direction in which the transmission path extends includes a direction parallel to a direction in which the etching solution moves and a direction inclined by 45 degrees relative to the direction in which the etching solution moves.

19. The transmission board production method according to claim 1, further comprising a step of forming, on the panel, a figure indicating a direction in which the transmission path extends, wherein
the etching step is performed on the panel on which the figure has been formed.
